(19) United States
(12) Patent Application Publication
(10) Pub. No.: US 2010/0059841 A1
(43) Pub. Date: Mar. 11, 2010

(54) IMAGE SENSOR AND METHOD FOR MANUFACTURING THE SAME

(76) Inventor: Ji Hoon Hong, Seoul (KR)

Correspondence Address: SALIWANCHIK LLOYD & SALIWANCHIK;A PROFESSIONAL ASSOCIATION, PO Box 142950, GAINESVILLE, FL, 32614, US

(21) Appl. No.: 12/548,960

(22) Filed: Aug. 27, 2009

(30) Foreign Application Priority Data
Sep. 11, 2008 (KR) 10-2008-0089688

(51) Int. Cl. H01L 31/0232; H01L 31/18

(52) U.S. Cl. 257/432; 438/69; 257/E31.127; 257/E21.211

(57) ABSTRACT

Disclosed are an image sensor and a method for manufacturing the same. The image sensor includes an image sensing device on a substrate, an interlayer dielectric layer over the image sensing device, and an aspheric microlens over the interlayer dielectric layer.

### CROSS-REFERENCE TO RELATED APPLICATION

This application claims the benefit under 35 U.S.C. §119 of Korean Patent Application No. 10-2008-0089688, filed Sep. 11, 2008, which is hereby incorporated by reference in its entirety.

### BACKGROUND

An image sensor is a semiconductor device for converting optical images into electric signals, and is generally classified into a charge coupled device (CCD) image sensor and a complementary metal oxide semiconductor (CMOS) image sensor (CIS).

According to the related art, a CIS microlens is smoothly curved by patterning photoresist and then reflowing the resultant structure through a bake process.

However, since a convex lens represents different refractive indexes of light at the center and the edge thereof due to an optical characteristic, an image may not be precisely focused on the surface of a photodiode. This is referred to as spherical aberration.

### BRIEF SUMMARY

An embodiment provides an image sensor capable of preventing spherical aberration and a method for manufacturing the same.

According to an embodiment, an image sensor includes an image sensing device on a substrate, an interlayer dielectric layer over the image sensing device, and an aspheric microlens over the interlayer dielectric layer.

According to an embodiment, a method for manufacturing an image sensor includes forming an image sensing device on a substrate, forming an interlayer dielectric layer over the image sensing device, and forming an aspheric microlens over the interlayer dielectric layer.

### BRIEF DESCRIPTION OF THE DRAWINGS

FIG. 1 is a cross-sectional view showing an image sensor according to an embodiment;

FIGS. 2 to 5 are cross-sectional views showing a method for manufacturing an image sensor according to the embodiment; and

FIG. 6 is a view showing the effect of the image sensor of an embodiment.

### DETAILED DESCRIPTION

Hereinafter, an image sensor and a method for manufacturing the same according to an embodiment will be described with reference to accompanying drawings.

In the description of embodiments, it will be understood that when a layer (or film) is referred to as being ‘on’ another layer or substrate, it can be directly on another layer or substrate, or intervening layers may also be present. Further, it will be understood that when a layer is referred to as being ‘under’ another layer, it can be directly under another layer, or one or more intervening layers may also be present. In addition, it will also be understood that when a layer is referred to as being ‘between’ two layers, it can be the only layer between the two layers, or one or more intervening layers may also be present.

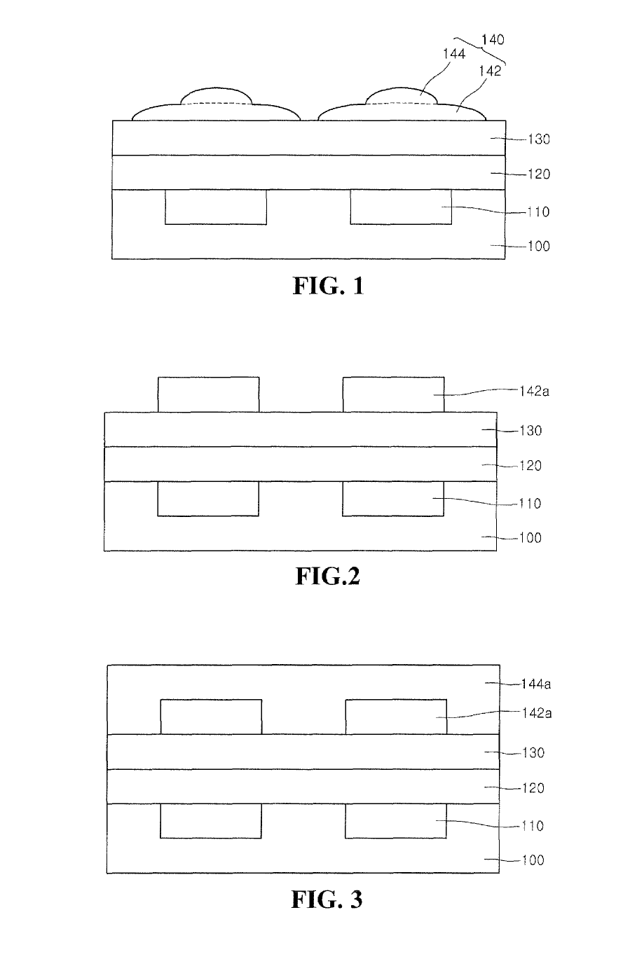

FIG. 1 is a cross-sectional view showing an image sensor according to an embodiment.

The image sensor according to an embodiment includes an image sensing device 110 formed on a substrate 100, an interlayer dielectric layer 120 formed on the image sensing device 110, and an aspheric microlens 140 formed on the interlayer dielectric layer 120.

The aspheric microlens 140 includes a lower microlens 142 and an upper microlens 144 formed on the lower microlens 142.

According to an embodiment, the image sensing device 110 may be a photodiode, but embodiments are not limited thereto. For example, the image sensing device 110 may be a photogate or the combination of the photodiode and the photogate.

In the image sensor according to embodiments of the present invention, an aspheric lens is manufactured through a microlens double coating process, thereby overcoming and/or minimizing spherical aberration. In other words, the shape of the microlens is changed to inhibit spherical aberration so that light refracted from the microlens can be more precisely focused on a photodiode.

Reference numerals of FIG. 1, which are not described, will be described below with respect to a method for manufacturing the image sensor.

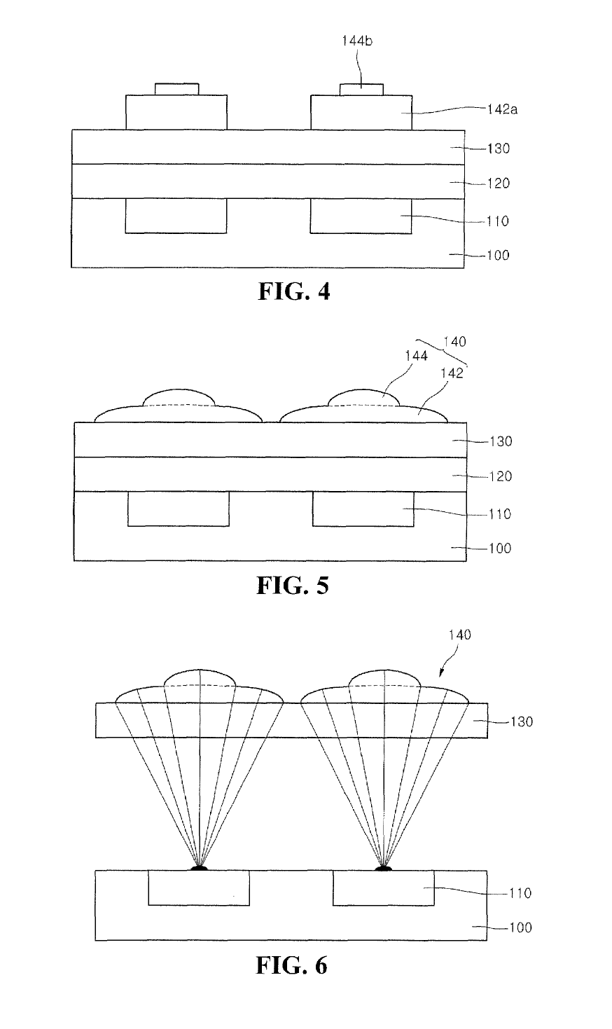

Hereinafter, a method for manufacturing an image sensor according to an embodiment will be described with reference to FIGS. 2 to 5.

First, an image sensing device 110 may be formed on a substrate 100. For example, a photodiode may be formed through an ion implantation process. Meanwhile, a readout circuitry (not shown) may be formed on the substrate 100 to deliver or read electronic information from the image sensing device 110.

Then, an interlayer dielectric layer 120 may be formed on the image sensing device 100. For example, an interlayer dielectric layer including TEOS may be formed on the image sensing device 110 and the readout circuitry, but the embodiment is not limited thereto.

Thereafter, a color filter layer 130 may be formed on the interlayer dielectric layer 120. For example, a color filter layer having primary colors (RGB) or complementary colors (CMYG) may be formed. In certain embodiments, a planarization layer (not shown) may be further formed on the color filter layer 130.

Hereinafter, a process of forming the aspheric microlens 140 will be described. In various embodiment, the aspheric microlens 140 can be formed on the color filter layer 130 (or on a planarization layer on the color filter layer 130) or on the interlayer dielectric layer 120.

Referring to FIG. 2, a lower microlens pattern 142a is formed on the color filter layer 130 or the interlayer dielectric layer 120. For example, the lower microlens pattern 142a may be formed by performing a PEP process using a negative photoresist (PR). In this case, since the lower microlens pattern 142a is formed by using the negative PR, the lower microlens pattern 142a is cured after an exposure process.

Next, as shown in FIG. 3, an upper microlens PR 144a is formed on the lower microlens pattern 142a.

An upper microlens pattern 144b may be formed through a PEP process using the upper microlens PR 144a. In this case, since the upper microlens PR 144A is a negative PR, a patterning process can be performed without an influence on the lower microlens pattern 142a.

According to embodiments, the upper microlens pattern 144b is formed to have a horizontal width narrower than that of the lower microlens pattern 142a, so that an aspheric microlens can be formed.

Thereafter, as shown in FIG. 5, a reflow process is performed with respect to the upper microlens pattern 144b and the lower microlens pattern 142a, thereby forming the aspheric microlens 140.

The aspheric microlens 140 includes the lower microlens 142 and the upper microlens 144 formed on the lower microlens 142.

According to an embodiment, the shapes of the upper microlens pattern 144b and the lower microlens pattern 142a are minimally changed at the center thereof, but edges of the upper microlens pattern 144b and the lower microlens pattern 142a are spread due to the reflow process, so the aspheric microlens 140 can be formed.

FIG. 6 is a view showing the effect of an image sensor of an embodiment.

In the image sensor and the method for manufacturing the same according to an embodiment, the shape of a microlens is changed to inhibit spherical aberration so that light refracted from the microlens can be precisely focused on the photodiode as illustrated by FIG. 6. In accordance with embodiments of the present invention, an aspheric lens is manufactured through a microlens double coating process to overcome spherical aberration.

Any reference in this specification to “one embodiment,” “an embodiment,” “example embodiment,” etc., means that a particular feature, structure, or characteristic described in connection with the embodiment is included in at least one embodiment of the invention. The appearances of such phrases in various places in the specification are not necessarily all referring to the same embodiment. Further, when a particular feature, structure, or characteristic is described in connection with any embodiment, it is submitted that it is within the purview of one skilled in the art to effect such feature, structure, or characteristic in connection with other ones of the embodiments.

Although embodiments have been described with reference to a number of illustrative embodiments thereof, it should be understood that numerous other modifications and embodiments can be devised by those skilled in the art that will fall within the spirit and scope of the principles of this disclosure. More particularly, various variations and modifications are possible in the component parts and/or arrangements of the subject combination arrangement within the scope of the disclosure, the drawings and the appended claims. In addition to variations and modifications in the component parts and/or arrangements, alternative uses will also be apparent to those skilled in the art.

What is claimed is:

1. An image sensor comprising:
an image sensing device on a substrate;
an interlayer dielectric layer over the image sensing device; and
an aspheric microlens over the interlayer dielectric layer.

2. The image sensor of claim 1, wherein the aspheric microlens includes a lower microlens and an upper microlens over the lower microlens.

3. The image sensor of claim 2, wherein the lower and upper microlenses are formed by using a negative photoresist.

4. The image sensor of claim 2, wherein the upper microlens has a horizontal width narrower than a horizontal width of the lower microlens.

5. A method for manufacturing an image sensor, the method comprising:
forming an image sensing device on a substrate;
forming an interlayer dielectric layer over the image sensing device; and
forming an aspheric microlens over the interlayer dielectric layer.

6. The method of claim 5, wherein the forming of the aspheric microlens comprises:
forming a lower microlens pattern;
forming an upper microlens pattern on the lower microlens pattern; and
performing a reflow process for the lower microlens pattern and the upper microlens pattern.

7. The method of claim 6, wherein the lower microlens pattern is formed by using a negative photoresist.

8. The method of claim 6, wherein the lower microlens pattern is cured through an exposure process when forming the lower microlens pattern.

9. The method of claim 6, wherein the upper microlens pattern is formed by using a negative photoresist.

10. The method of claim 6, wherein the upper microlens pattern is cured through an exposure process when forming the upper microlens pattern.

11. The method of claim 6, wherein, in the forming of the upper microlens pattern, the upper microlens pattern is formed to have a horizontal width narrower than a horizontal width of the lower microlens pattern.
